(19) United States
(12) Patent Application Publication
(10) Pub. No.: US 2026/0130220 A1
(43) Pub. Date: May 7, 2026

(54) POP PACKAGE STRUCTURE AND MANUFACTURING METHOD THEREOF

(71) Applicant: Samsung Electronics Co., Ltd., Suwon-si, (KR)

(72) Inventors: Minyan WU, Suzhou (CN); Yonghua ZHOU, Suzhou (CN)

(73) Assignee: Samsung Electronics Co., Ltd., Suwon-si (KR)

(21) Appl. No.: 18/956,498

(22) Filed: Nov. 22, 2024

(30) Foreign Application Priority Data
Nov. 7, 2024 (CN) 202411586038.1

(51) Int. Cl. H01L 23/427; H01L 23/31; H01L 23/373; H01L 23/498; H01L 23/538; H01L 25/00; H01L 25/10

(52) U.S. Cl. CPC H10W 40/73; H10W 40/257; H10W 70/611; H10W 74/121; H10W 90/00; H10W 90/401; H10W 90/701

(57) ABSTRACT

Example embodiments are directed to a package-on-package (PoP) package structure and a method of manufacturing the same. The PoP package structure includes a substrate, a first package on the substrate, a second package on the first package, a first thermal conductive layer between the first package and the second package, a second thermal conductive layer on the second package, and a thermal interface material layer between the first package and the substrate. The first thermal conductive layer passes through a via penetrating the first package to contact the thermal interface material layer, and the second thermal conductive layer passes through a via penetrating the second package to contact the first thermal conductive layer.

### CROSS-REFERENCE TO RELATED APPLICATION

This application claims priority under 35 U.S.C. § 119 to Chinese Patent Application No. 202411586038.1, filed on Nov. 7, 2024, the disclosure of which is incorporated herein by reference in its entirety.

### BACKGROUND

Example embodiments are directed to a semiconductor package and a method of manufacturing the same.

Due to rapid development of the electronic industry and user demands, electronic devices are becoming smaller and lighter, and thus, highly integrated semiconductor chips as core components of the electronic devices become useful. In addition, as mobile products are widely used, small-sized multi-functional electronic devices become popular. Therefore, a package-on-package (PoP) package structure in which an upper package having a different function from a lower package is stacked on the lower package has been proposed.

### SUMMARY

Example embodiments are directed to improving heat dissipation of the package-on-package (PoP) package structures.

Example embodiments are directed to a PoP package structure that improves the heat dissipation performance through a combination of a heat dissipation member disposed between a SOC package and a memory package, a heat dissipation member disposed between the SOC package and a PCB plate as well as a heat dissipation member disposed on a surface of the memory package.

In addition, some example embodiments are directed to a method of manufacturing the PoP package structure.

According to some example embodiments of the present disclosure, a PoP package structure may include a substrate, a first package on the substrate, and including a first base substrate, a first chip on the first base substrate, and a first mold layer on the first base substrate and encapsulating or at least partially encapsulating the first chip, a second package on the first package, and including a second base substrate, a second chip on the second base substrate, and a second mold layer on the second base substrate and encapsulating or at least partially encapsulating the second chip, a first thermal conductive layer between an upper surface of the first package and a lower surface of the second package, and a thermal interface material layer between a lower surface of the first package and an upper surface of the substrate. The first thermal conductive layer contacts the thermal interface material layer through a via defined in the first package.

According to some example embodiments, the first thermal conductive layer may include a thermal conductive insulating material.

According to some example embodiments, the POP package structure may further include a second thermal conductive layer on an upper surface of the second package. The second thermal conductive layer contacts the first thermal conductive layer through a via penetrating the second package.

According to some example embodiments, the second thermal conductive layer may include a thermal conductive insulating material.

According to some example embodiments, the first thermal conductive layer and the second thermal conductive layer may include materials that are same as each other.

According to some example embodiments, the first thermal conductive layer and the second thermal conductive layer may include materials that are different from each other.

According to some example embodiments, an upper surface of the second thermal conductive layer is at a same level as the upper surface of the second package.

According to some example embodiments, the thermal interface material layer may include a thermal conductive matrix and a phase change composite material dispersed in the thermal conductive matrix.

According to some example embodiments, the thermal conductive matrix may have an insulating property.

According to some example embodiments, the phase change composite material may include a phase change material and a wrapping material wrapping the phase change material.

According to some example embodiments, a method of manufacturing a PoP package structure may include providing a first package including a first base substrate, a first chip on the first base substrate, and a first mold layer on the first base substrate and encapsulating or at least partially encapsulating the first chip, performing a drilling process on the first package to form a first via penetrating the first package, coating a high thermal conductive insulating material on an upper surface of the first package to form a first thermal conductive layer, coating a phase change composite material on an upper surface of a substrate, bonding the first package formed with a first thermal conductive layer on the upper surface thereof and the substrate coated with the phase change composite material on the upper surface thereof with each other, providing a second package including a second base substrate, a second chip on the second base substrate, and a second mold layer on the second base substrate and encapsulating or at least partially encapsulating the second chip, bonding the second package and the first package bonded to the substrate with each other, and filing a thermal conductive matrix in a space between the substrate and the first package, to form a thermal interface material layer. The first thermal conductive layer is in contact with the thermal interface material layer through the first via.

According to some example embodiments, the method may further include after forming the first thermal conductive layer, performing an etching process on the upper surface of the first thermal conductive layer to form a first recess.

According to some example embodiments, the method may further include performing an etching process on an upper surface of the second package to form a second recess, performing a drilling process on the second package to form a second via penetrating the second package, and coating a thermal conductive insulating material on the upper surface of the second package to form a second thermal conductive layer. The second thermal conductive layer fills the second recess and the second via, and contacts the first thermal conductive layer through the second via.

According to some example embodiments, the first thermal conductive layer and the second thermal conductive layer may include thermal conductive insulating materials that are same as each other.

According to some example embodiments, the first thermal conductive layer and the second thermal conductive layer may include thermal conductive insulating materials that are different from each other.

According to some example embodiments, an upper surface of the second thermal conductive layer is at a same level as the upper surface of the second package.

According to some example embodiments, the thermal conductive matrix may have an insulating property.

According to some example embodiments, the phase change composite material may include a phase change material and a wrapping material wrapping the phase change material.

### BRIEF DESCRIPTION OF THE DRAWINGS

The above and other aspects, features and other advantages of the example embodiments will be more clearly understood from the following detailed description, taken in conjunction with the accompanying drawings.

FIG. 1 illustrates a package-on-package (PoP) package structure.

FIG. 2 illustrates a PoP package structure, according to some example embodiments of the present disclosure.

FIG. 3 illustrates a PoP package structure, according to some example embodiments of the present disclosure.

FIGS. 4A, 4B, 4C, 4D, 4E, 4F, 4G, 4H, 4I, and 4J illustrate operations in a method of manufacturing a PoP package structure, according to some example embodiments of the present disclosure.

### DETAILED DESCRIPTION

Example embodiments of the present disclosure are described with reference to the accompanying drawings. However, the example embodiments may be implemented in many different forms, and should not be interpreted to be limited to the example embodiments set forth herein. Rather, the example embodiments are provided so that the present disclosure will be thorough and complete, and will fully convey the concepts disclosed herein to those of ordinary skill in the art. Throughout the specification, the same components are referred to by the same reference numerals, and the repeated descriptions thereof may be omitted for conciseness of the description.

Unless otherwise defined, all terms (including technical and scientific terms) used herein have the same meaning as commonly understood by those of ordinary skill in the art of which the present disclosure is as a part. Terms, such as those defined in commonly used dictionaries, should be interpreted as having a meaning that is consistent with their meaning in the context of the relevant art, and will not be interpreted in an idealized or overly formal sense unless expressly so defined herein.

In the following description, for the purposes of explanation, numerous specific details are set forth to provide a thorough understanding of various example embodiments. It is apparent, however, that various example embodiments may be practiced without these specific details or with one or more equivalent arrangements.

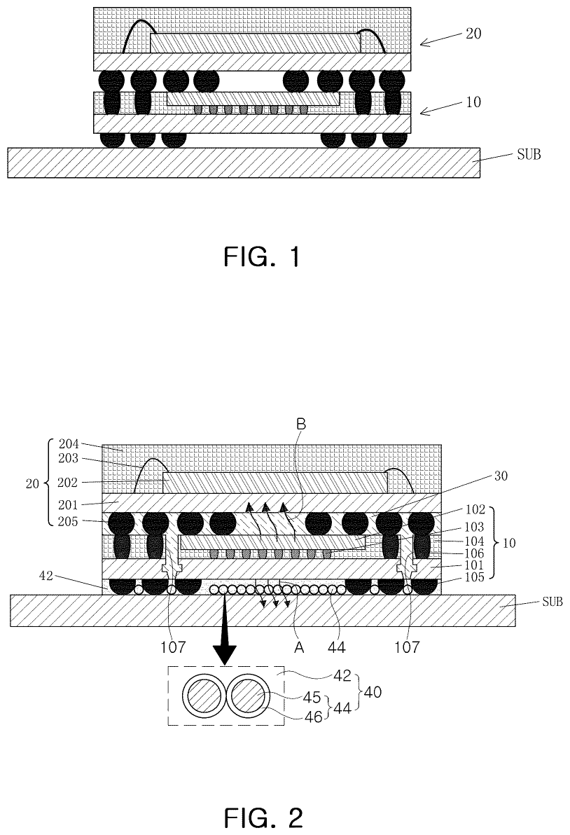

FIG. 1 illustrates a package-on-package (PoP) package structure 1 that may include a substrate SUB and a system-on-chip (SOC) package 10 and a memory package 20 sequentially stacked in a vertical direction on the substrate SUB. In operation, the SOC package 10 will generate heat, which should be dissipated. However, the heat dissipation area of the PoP package structure 1 is relatively small, and the heat generated by the SOC package 10 may not be easily dissipated and temperature in the PoP package structure 1 may rise causing a hot spot to form. This may eventually cause failure of the PoP package structure 1, thereby affecting the package performance.

FIG. 2 illustrates a PoP package structure, according to some example embodiments of the present disclosure.

Referring to FIG. 2, a PoP package structure 2 according to some example embodiments may include a substrate SUB, and a System-on-Chip (SOC) package 10 and a memory package 20 sequentially stacked along a vertical direction on the substrate SUB. However, an arrangement of the PoP package structure is not limited thereto. For example, in some other example embodiments, the PoP package structure may include three or more semiconductor packages sequentially stacked along a vertical direction on the substrate SUB, and a suitable type of the semiconductor package may be selected without limitation.

The substrate SUB may be a printed circuit board (PCB). For example, the substrate SUB may be a single-layer printed circuit board or a multi-layer printed circuit board. However, example embodiments are not limited thereto. In some example embodiments, for example, the substrate SUB may include an upper bonding pad disposed on an upper surface, a lower bonding pad disposed on a lower surface, and internal leads disposed inside the substrate SUB to electrically connect the upper bonding pad and the lower bonding pad.

In some example embodiments, the substrate SUB may include at least one material selected from among a phenolic resin, an epoxy resin, and polyimide. The substrate SUB may include, for example, at least one material selected from among flame retardant 4 (FR4), a tetrafunctional epoxy resin, polyphenyl ether, an epoxy resin/a polyphenylene oxide, bismaleimide triazine (BT), polyamide, cyanoacrylate ester, polyimide, and a liquid crystal polymer. However, example embodiments are not necessarily limited thereto.

A plurality of pads and/or conductive traces may be disposed on the upper surface of the substrate SUB. In an embodiment, the conductive traces may include signal traces or ground traces for input/output connections of the SOC package 10 and the memory package 20. The pads are disposed on the upper surface of the substrate SUB, and connected to corresponding conductive traces.

The SOC package 10 may be a three-dimensional (3D) semiconductor package, and include a first base substrate 101, a system-on-chip chip 102, system-on-chip chip solder balls 103 electrically connecting the system-on-chip chip 102 to the internal lead disposed in the first base substrate 101, and a first mold layer 104 disposed on the first base substrate 101 and encapsulating or at least partially encapsulating the system-on-chip chip 102 and the system-on-chip chip solder balls 103 on the first base substrate 101.

In some example embodiments, the system-on-chip chip 102 may include a Central Processing Unit (CPU), a Graphic Processing Unit (GPU), a Dynamic Random Access Memory (DRAM) controller, and the like, but example embodiments are not limited thereto. The system-on-chip chip 102 may be disposed on an upper surface of the first base substrate 101 and spaced away from the substrate SUB. The system-on-chip chip 102 may be manufactured by using, for example, a flip chip technology.

The SOC package 10 may be connected to the upper surface of the substrate SUB through external solder balls 105 disposed on a lower surface of the first base substrate 101.

In some example embodiments, the first base substrate 101 may be a silicon substrate, a silicon-germanium substrate, a germanium substrate, or a structure including a single crystal silicon substrate and a single crystal epitaxial layer grown therefrom. However, example embodiments are not limited thereto.

In some example embodiments, the system-on-chip chip solder balls 103 and the external solder balls 105 may include a solder material. In some example embodiments, the solder material may be or include tin (Sn), indium (In), bismuth (Bi), antimony (Sb), copper (Cu), silver (Ag), zinc (Zn), lead (Pb) and/or an alloy thereof. However, the system-on-chip chip solder balls 103 and the external solder balls 105 may include other materials, in other example embodiments.

In some example embodiments, the first mold layer 104 may be or include an ultraviolet curing polymer or a thermal curing polymer. For example, the first mold layer 104 may be or include a non-conductive material such as an epoxy molding compound (EMC), an Ajinomoto buildup film (ABF), FR-4, bismaleimide triazine (BT) or the like. However, example embodiments are not necessarily limited thereto. The first mold layer 104 may be applied or formed when in a liquid or fluid state on the substrate, and then may be cured through a chemical reaction or similar processes.

The memory package 20 may include a Dynamic Random Access Memory (DRAM) package and/or other suitable memory packages. In some example embodiments, the memory package 20 may include a second base substrate 201, a memory chip 202, a bonding wire 203 electrically connecting the memory chip 202 to an upper surface of the second base substrate 201 that faces away from the substrate SUB, and a second mold layer 204 disposed or formed on the second base substrate 201. The second mold layer 204 may encapsulate or at least partially encapsule the memory chip 202 and the bonding wire 203 on the second base substrate 201.

In some example embodiments, the memory chip 202 may include a volatile memory chip (such as a Dynamic Random Access Memory (DRAM) or a Static Random Access Memory (DRAM)) or a non-volatile memory chip (such as a Phase change Random Access Memory (PcRAM), a Magnetic Random Access Memory (MRAM), a Ferroelectric Random Access Memory (FeRAM) or a Resistive Random Access Memory (RRAM)). However, example embodiments are not limited thereto. The memory chip 202 may be disposed on an upper surface of the second base substrate 201 that faces away from the substrate SUB. The memory chip 202 may be attached on the second base substrate 201 using an adhesive. In some example embodiments, the memory chip 202 may be electrically connected to the second base substrate 201 using the bonding wire 203 and the bonding pad. However, example embodiments are not limited thereto, and example embodiments may be modified depending on application and/or design.

The memory package 20 may be connected to the SOC package 10 through inter-chip solder balls 205 disposed on a lower surface of the second base substrate 201 (e.g., the surface of the second base substrate 201 that faces the substrate SUB).

In some example embodiments, similar to the first base substrate 101, the second base substrate 201 may be a silicon substrate, a silicon-germanium substrate, a germanium substrate, or a structure including a single crystal silicon substrate and a single crystal epitaxial layer grown therefrom. However, in other example embodiments, the second base substrate 201 may include other materials depending on application and/or design.

The first base substrate 101 and the second base substrate 201 may be electrically connected to each other through the inter-chip solder balls 205 and connection solder balls 106, wherein the inter-chip solder balls 205 may be disposed between the second base substrate 201 of the memory package 20 and the first mold layer 104 of the SOC package 10, and the connection solder balls 106 may penetrate the first mold layer 104 and may be connected to the inter-chip solder balls 205 and the bonding pads on the first base substrate 101. The connection solder balls 106 may be connected between the first base substrate 101 and the second base substrate 201, and distributed around a periphery of the system-on-chip chip 102, to realize the physical connection and signal connection between the first base substrate 101 and the second base substrate 201.

The bonding pad that may be disposed on a surface of the memory chip 202 opposite to the system-on-chip chip 102 (e.g., an upper surface of the memory chip 202) may be electrically connected to the bonding pad disposed on an upper surface of the second base substrate 201 through the bonding wire 203. In some example embodiments, the bonding wire 203 may be a copper wire, an aluminum wire, a silver wire, a gold wire, or the like. However, example embodiments are not limited thereto and the bonding wire 203 may be or include any conductive material depending on application and/or design.

In some example embodiments, similar to the first mold layer 104, the second mold layer 204 may be or include an ultraviolet curing polymer or a thermal curing polymer. For example, the second mold layer 204 may include a non-conductive material such as an epoxy molding compound (EMC), an Ajinomoto buildup film (ABF), FR-4, bismaleimide triazine (BT) or the like. However, example embodiments are not limited thereto. The second mold layer 204 may be applied when in a liquid or fluid state on the substrate, and then may be cured through a chemical reaction or similar other processes.

In some example embodiments, a thermal conductive layer 30 may be disposed between the SOC package 10 and the memory package 20. In some example embodiments, the thermal conductive layer 30 may be disposed between an upper surface of the SOC package 10 and a lower surface of the memory package 20. In some example embodiments, the thermal conductive layer 30 may be disposed between a lower surface of the second base substrate 201 of the memory package 20 and an upper surface of the first mold layer 104 of the SOC package 10, and may pass through vias 107 penetrating the SOC package 10 to extend to the lower surface of the first base substrate 101. In some example embodiments, the thermal conductive layer 30 may contact the SOC package 10. In some example embodiments, the thermal conductive layer 30 may only fill a portion (e.g., a lower portion) of the space between the second base substrate 201 of the memory package 20 and the first mold layer 104 of the SOC package 10. In some other example embodiments, the thermal conductive layer 30 may fill an entirety of the space between the second base substrate 201 of the memory package 20 and the first mold layer 104 of the SOC package 10. In some example embodiments, the number of vias 107 in the SOC package 10 may be increased or decreased and/or and the locations in the SOC package 10 may be changed depending on application and/or design.

In some example embodiments, in order to improve or maximize the heat dissipation capability, the thermal conductive layer 30 may, in addition to covering an entirety of the upper surface of the first mold layer 104, may also cover a side surface of the first mold layer 104. However, example embodiments are not limited thereto. In some example embodiments, the thermal conductive layer 30 may partially cover the upper surface of the first mold layer 104. For example, the thermal conductive layer 30 may only cover a portion of the upper surface of the first mold layer 104 that may vertically overlap the system-on-chip chip 102. The location of the thermal conductive layer 30 may thus be changed and/or the size of the thermal conductive layer 30 may be increased or decreased depending on application and/or design.

The thermal conductive layer 30 may be or include an insulating material having a high thermal conductivity (e.g., a high thermal conductive insulating material), so that heat generated by the SOC package 10 may be dissipated or conducted with relative ease through the thermal conductive layer 30 to the first base substrate 101 and the second base substrate 201 for effective heat dissipation. The thermal conductive layer 30 may limit or minimize or prevent a short circuit between the first base substrate 101 and the second base substrate 201, and improve heat conduction. In some example embodiments, in order to limit or minimize or prevent a short circuit between connection points, the thermal conductive layer 30 may limit use of a conductive material, such as metal, therein. For instance, the thermal conductive layer 30 may not include any conductive material, or a conductive material may be present in relatively minor quantities so as to provide poor conducting properties. In some example embodiments, the thermal conductivity of the high thermal conductive insulating material may be greater than 1 W/mK (or about 1 W/mK). In some other example embodiments, the thermal conductivity may be higher, 2 W/mK (or about 2 W/mK). However, example embodiments are not limited thereto, and the thermal conductivity may be varied as needed by application and/or design. In some example embodiments, the high thermal conductive insulating material may be or include aluminum nitride, aluminum oxide, silicon nitride, graphene, thermal grease, a combination thereof, or the like. However, example embodiments are not limited thereto, and other thermally conductive materials may be used. In some example embodiments, the thermal conductive layer 30 may be or include a material such as a metal thermal conductive plate, in addition or as an alternative to the high thermal conductive insulating material. When the metal thermal conductive plate is used, an additional insulating layer may be disposed around the metal thermal conductive plate in order to limit or minimize or avoid short circuit conditions.

In some example embodiments, the thermal conductive layer 30 may have adhesive properties that improve or enhance the bonding between the second base substrate 201 of the memory package 20 and the first mold layer 104 of the SOC package 10. Additionally or alternatively, the thermal conductive layer 30 may be elastic (or have elastic properties) and the thermal conductive layer 30 may be elastically deformed when an external force or pressure is applied thereto. As a result, voids may be limited when the thermal conductive layer 30 occupies spaces between the second base substrate 201 and the first mold layer 104, and the thermal conductive layer 30 may provide a relatively stable connection between the second base substrate 201 and the first mold layer 104. In some example embodiments, the thermal conductive layer 30 may be a thermal conductive adhesive block, which not only has elasticity and adhesion, but also has a relatively high thermal conductivity and provides electrical insulation. However, example embodiments are not limited thereto, and other materials may be used as the thermal conductive layer 30 as needed by application and/or design. It will be understood that, for the purposes of discussion, “insulation,” as used herein, may refer to electrical insulation, unless otherwise specified.

A thermal interface material layer 40 may be disposed between the SOC package 10 (e.g., the first base substrate 101) and the substrate SUB, and may be in contact with the thermal conductive layer 30 through the vias 107, to provide heat conduction. In some example embodiments, the thermal interface material layer 40 may be disposed between a lower surface of the SOC package 10 and an upper surface of the substrate SUB. The thermal interface material layer 40 may be or include a thermal conductive matrix 42 and/or a phase change composite material 44 dispersed in the thermal conductive matrix 42. In some example embodiments, a combination of the thermal conductive matrix 42 and the phase change composite material 44 may provide a more effective or improved thermal conductive effect. However, example embodiments are not limited thereto. For example, in some other example embodiments the thermal interface material layer 40 may only include the thermal conductive matrix 42. In some example embodiments, in order to avoid or minimize or limit short circuit between the first base substrate 101 and the substrate SUB, the thermal conductive matrix 42 may be insulating, and, in order to achieve good or improved heat conduction, the thermal conductive matrix 42 may have relatively higher thermal conductivity. In addition, the thermal interface material layer 40 may also adhere or couple or attach the SOC package 10 to the upper surface of the substrate SUB, and thus, the thermal conductive matrix 42 may have adhesive properties. Further, the thermal conductive matrix 42 may have elastic properties. In some example embodiments, the thermal interface material layer 40 may be elastically deformed when an external force or pressure is applied thereto. As result, voids may be limited when the thermal interface material layer 40 occupies spaces between the first base substrate 101 and the substrate SUB and the thermal interface material layer 40 may provide a relatively stable connection between the first base substrate 101 and the substrate SUB.

In some example embodiments, the thermal conductive matrix 42 of the thermal interface material layer 40 may be similar to the high thermal conductive insulating material of the thermal conductive layer 30. In some example embodiments, thermal conductive matrix 42 of the thermal interface material layer 40 may be a material having a fluidity higher than a fluidity of the high thermal conductive insulating material of the thermal conductive layer 30. In some example embodiments, in order to achieve improved underfill, the thermal conductive matrix 42 having higher fluidity may be beneficial. In some example embodiments, in order to achieve improved thermal conduction efficiency, the thermal conductive matrix 42 may have a relatively higher thermal conductivity (e.g., greater than 1 W/mK (or about 1 W/mK)). The thermal conductive matrix 42 may include, for example, thermal grease, but, in some example embodiments, other thermally conductive materials may be used.

In some example embodiments, the phase change composite material 44 used in the thermal interface material layer 40 may include a phase change material 45 and a wrapping material 46 wrapping or enclosing or surrounding the phase change material 45.

In some example embodiments, the phase change material 45 may have an ability to change its physical state within a certain temperature range, thereby releasing or absorbing a relatively large amount of heat upon phase change and achieving a heating or cooling function. Taking the solid-liquid phase as an example, upon heating to a melting temperature, a phase change occurs from a solid state to a liquid state, and in the melting process, the phase change material 45 absorbs and stores a large amount of latent heat. By including the phase change material 45 in the thermal conductive matrix 42, the ability of changing the physical state of the phase change material 45 may be used to significantly improve the heat dissipation ability of the PoP package structure. The phase change material 45 can be a material with a relatively low phase change temperature and a relatively large phase change latent heat. In some example embodiments, the phase change material 45 may be a susceptible phase change material. For example, the phase change material 45 may be R-134a or R113 with the highest boiling point between 60° C. (or about 60° C.) and 70° C. (or about 70° C.) , or the like. However, example embodiments are not limited thereto and the properties of the phase change material 45 can be modified depending on application and/or design.

In some example embodiments, the wrapping material 46 may increase or improve the thermal conductivity of the phase change material 45 and prevent, reduce or minimize leakage of the phase change material 45. The wrapping material 46 may be or include, for example, a metal (e.g., copper, aluminum, etc.), but is not limited thereto. In some example embodiments where the phase change composite material 44 includes a metal outer layer (e.g., the phase change composite material 44 is a liquid metal phase change material), the phase change composite material 44 may have high thermal conductivity and high heat dissipation efficiency.

A content of the phase change composite material 44 in the thermal interface material layer 40 is not particularly limited, but may be determined according to the volume of the phase change material 45 and the capacity of the wrapping material 46.

In some example embodiments, the thermal conductive layer 30 is in contact with the second base substrate 201, and thus, heat generated by the system-on-chip chip 102 may be transferred upward (generally indicated by the arrows B) through the thermal conductive layer 30 to the second base substrate 201 and dissipated. The thermal conductive layer 30 may extend to the lower surface of the first base substrate 101 through the via 107 penetrating the SOC package 10, and may contact with the thermal interface material layer 40 disposed between the SOC package 10 (e.g., the first base substrate 101) and the substrate SUB. Thus, the heat generated by the system-on-chip chip 102 may be transferred downward (generally indicated by the arrows A) through the thermal conductive layer 30 to the first base substrate 101 and the substrate SUB and dissipated. In some example embodiments, since the thermal conductivity of the thermal interface material layer 40 is higher than the thermal conductivity of the second base substrate 201, the heat generated by the system-on-chip chip 102 may tend to be transferred downward for relatively rapid heat dissipation.

In some example embodiments, the thermal conductive layer 30 may maintain contact between the SOC package 10 and the second base substrate 201. The thermal interface material layer 40 may maintain contact of the first base substrate 101 and the thermal conductive layer 30 with the substrate SUB. Therefore, the internal contact thermal resistance of the PoP package structure 2 may be reduced, and the heat dissipation efficiency may be improved.

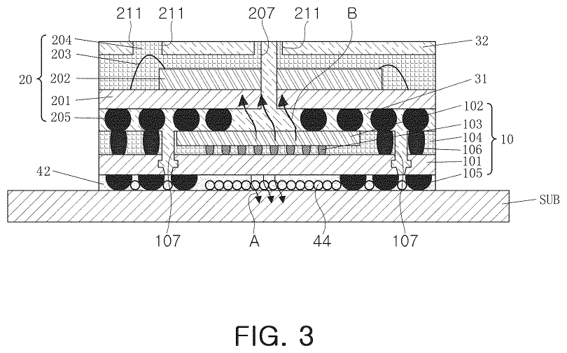

FIG. 3 illustrates a PoP package structure 3, according to some example embodiments of the present disclosure.

The PoP package structure 3 of FIG. 3 may be the same in some respects as the PoP package structure 2 of FIG. 2, and therefore may be best understood with reference thereto where like numerals indicate like elements not described again in detail. In the PoP package structure 3, the thermal conductive layer 30 may include a lower thermal conductive layer 31 and an upper thermal conductive layer 32.

Referring to FIG. 3, the lower thermal conductive layer 31 may be disposed between the SOC package 10 and the memory package 20. In some example embodiments, the lower thermal conductive layer 31 may be disposed between the upper surface of the SOC package 10 and the lower surface of the memory package 20. In some example embodiments, the lower thermal conductive layer 31 may be disposed between the second base substrate 201 of the memory package 20 and the first mold layer 104 of the SOC package 10, and may pass through the vias 107 penetrating the SOC package 10 to extend to the lower surface of the first base substrate 101 to be connected to the thermal interface material layer 40.

In some example embodiments, the upper thermal conductive layer 32 may be disposed on the upper surface of the memory package 20 (e.g., the second mold layer 204), and may pass through one or more vias 207 (one shown in FIG. 3) penetrating the memory package 20 to extend to the lower surface of the second base substrate 201 to be connected to the lower thermal conductive layer 31. In order to reduce the overall thickness of the PoP package structure 3, the upper thermal conductive layer 32 may be disposed or formed such that the upper surface thereof is located at a same level as the upper surface of the memory package 20 (e.g., an upper surface of the second mold layer 204). In some example embodiments, the upper thermal conductive layer 32 may be disposed or formed in recesses 211 formed in the upper surface of the second mold layer 204.

The lower thermal conductive layer 31 and the upper thermal conductive layer 32 may be the same as the thermal conductive layer 30 described above with reference to FIG. 2. Therefore, for the sake of brevity of description, a description thereof is omitted.

In some example embodiments, the lower thermal conductive layer 31 and the upper thermal conductive layer 32 may include high thermal conductive insulating materials that are the same as each other or different from each other.

In some example embodiments, the lower thermal conductive layer 31 and the upper thermal conductive layer 32 may cover surfaces of the SOC package 10 and the memory package 20, and may penetrate the SOC package 10 and the memory package 20 (e.g., the first base substrate 101 and the second base substrate 201). Thermal conductive materials inside the SOC package 10 and the memory package 20 may be connected to each other (e.g., connected in series), so that a heat dissipation path may be formed. As such, the heat generated by the system-on-chip chip 102 may not only be transferred upward (generally indicated by the arrows B) through the lower thermal conductive layer 31 to the second base substrate 201 and the upper thermal conductive layer 32 for dissipation, but also may be transferred downward (generally indicated by the arrows A) through the lower thermal conductive layer 31 to the first base substrate 101, the thermal interface material layer 40 and the substrate SUB for dissipation. As a result, the heat dissipation performance of the PoP package structure may be further improved.

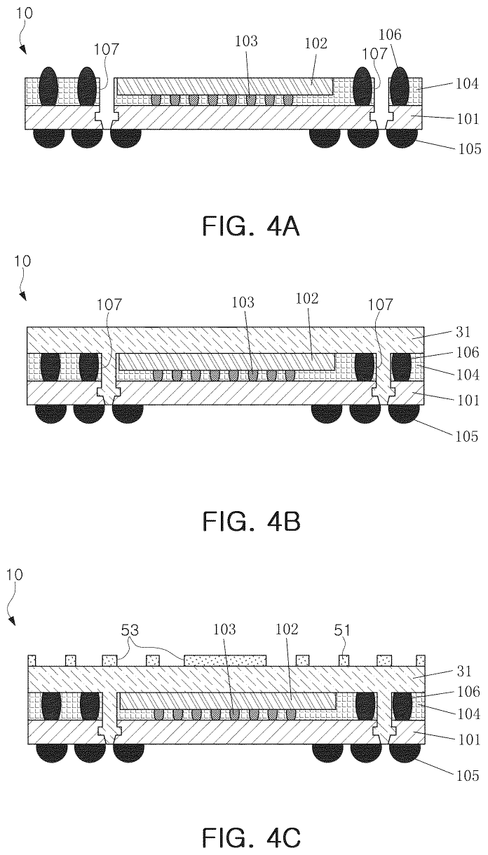

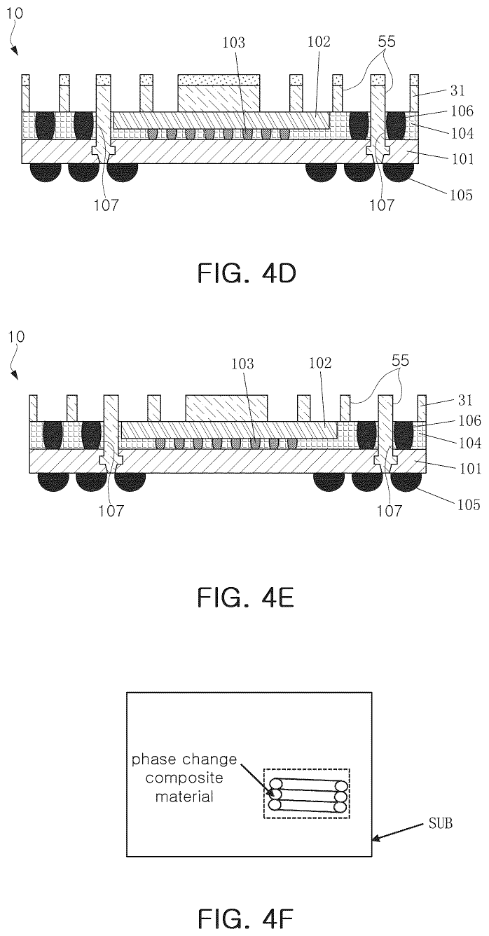

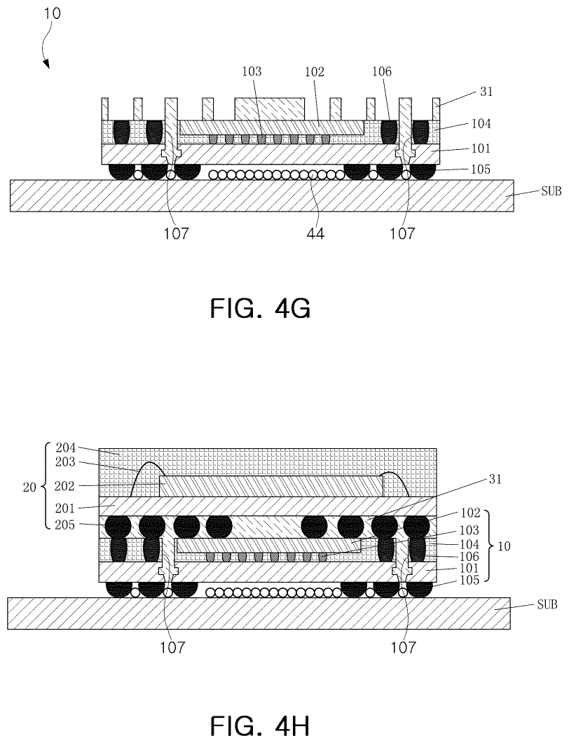

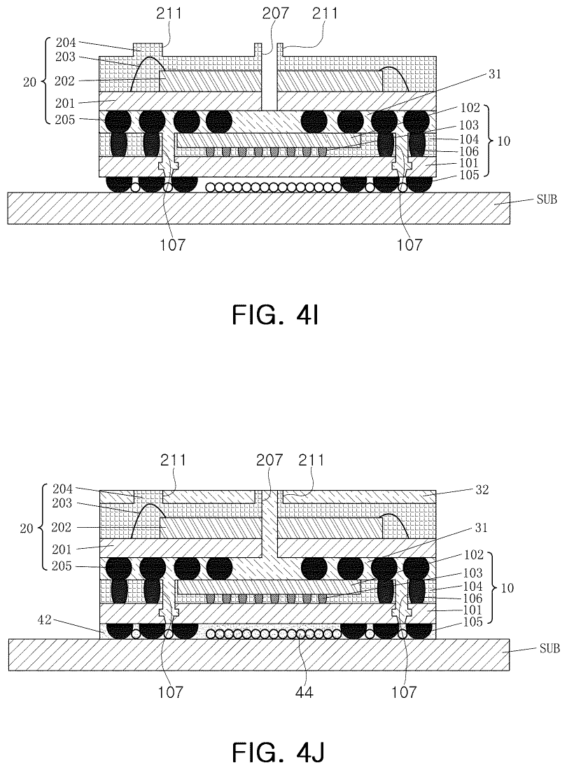

FIGS. 4A-4J illustrate operations in a method of manufacturing a PoP package structure, according to some example embodiments of the present disclosure. For the purposes of discussion, the manufacturing method illustrated in FIGS. 4A-4J may relate to the manufacturing of the PoP package structure 3 of FIG. 3, and is discussed with reference to FIG. 3. It is understood that additional operations can be provided before, during, and after the operations in FIGS. 4A-4J, and some of the operations described below can be replaced or eliminated, for additional embodiments of the method. The order of the operations/processes may be interchangeable, or two or more operations can be performed simultaneously.

Referring to FIGS. 3 and 4A, a SOC package 10 may be provided. The SOC package 10 may be a three-dimensional (3D) semiconductor package, and may include a first base substrate 101, a system-on-chip chip 102, system-on-chip chip solder balls 103 electrically connecting the system-on-chip chip 102 to the internal lead disposed in the first base substrate 101, a first mold layer 104 disposed or formed on the first base substrate 101 and encapsulating and at least partially encapsulating the system-on-chip chip 102 and the system-on-chip chip solder balls 103 on the first base substrate 101, external solder balls 105 disposed on a lower surface of the first base substrate 101 opposite to the system-on-chip chip 102, and connection solder balls 106 distributed around a periphery of the system-on-chip chip 102 and penetrating the first mold layer 104 and connected to internal leads in the first base substrate 101.

A drilling process may be performed on the SOC package 10 to form vias 107 in the SOC package 10. The vias 107 may penetrate the entire SOC package 10. In some example embodiments, the vias 107 may extend from the upper surface of the first mold layer 104 to the lower surface of the first base substrate 101. In some example embodiments, in order to achieve improved heat conduction, the size (e.g., cross-sectional area) of at least a portion of the via 107 in the first base substrate 101 may be larger than the size of the via 107 in the first mold layer 104. However, example embodiments are not limited thereto, and the via dimensions may be modified as needed by application and/or design.

Referring to FIGS. 3 and 4B, a high thermal conductive insulating material may be coated or formed on the upper surface of the SOC package 10 to form a lower thermal conductive layer 31.

In the coating or forming process, the high thermal conductive insulating material may fill the via 107 formed in the SOC package 10. In addition, the high thermal conductive insulating material may also be coated or formed on a side surface of the SOC package 10.

In some example embodiments, the high thermal conductive insulating material may have improved thermal conductivity and insulating properties, and may be or include a thermal conductive insulating rubber, an alumina oxide ceramic, a boron nitride ceramic, or the like. However, other materials having desired thermal conductivity and insulating properties may also be used.

In some example embodiments, a thickness of the high thermal conductive insulating material coated on the upper surface of the SOC package 10 may be less than or equal to a gap between the SOC package 10 and the memory package 20. In some example embodiments, the thickness of the high thermal conductive insulating material coated on the upper surface of the SOC package 10 may be equal to an interval between the SOC package 10 and the memory package 20 (e.g., completely filling the gap between the SOC package 10 and the memory package 20).

Referring to FIGS. 3, 4C and 4D, a photoresist pattern 51 having a plurality of openings 53 may be formed on the lower thermal conductive layer 31 by initially forming a photoresist layer on the lower thermal conductive layer 31 and then patterning the photoresist layer to create the plurality of openings 53. The lower thermal conductive layer 31 may be partially removed using the photoresist pattern 51 as an etching mask, to form a first recess 55 in the lower thermal conductive layer 31. The lower thermal conductive layer 31 may be partially removed through a dry etching process. However, other methods may also be used to form the first recess 55.

A width of the first recess 55 may be determined in consideration of a width of an inter-chip solder ball 205. A position of the first recess 55 may be determined in consideration of a position of the inter-chip solder ball 205. The first recess 55 may be formed to penetrate the lower thermal conductive layer 31.

Referring to FIG. 4E, the photoresist pattern may be removed or stripped.

Referring to FIGS. 3 and 4F, a substrate SUB may be provided. In some example embodiments, the substrate SUB may be a printed circuit board (PCB). However, the example embodiments are not limited thereto, and other types of substrates may also be used.

Next, a phase change composite material 44 may be coated on the substrate SUB. The phase change composite material 44 may be disposed on the substrate SUB by vacuum or capillary action. However, in other example embodiments, the phase change composite material 44 may be adhered on or attached to the substrate SUB using an adhesive or other fasteners.

In some example embodiments, as illustrated in FIG. 3, the position of the phase change composite material 44 on the substrate SUB may be determined based on the positions of the external solder balls 105 of the SOC package 10.

Referring to FIGS. 3 and 4G, the SOC package 10 formed in FIG. 4E may be attached to the substrate SUB formed in FIG. 4F.

In an embodiment, the SOC package 10 may be positioned on the upper surface of the substrate SUB. For example, the external solder balls 105 of the SOC package 10 may be connected with internal leads of the substrate SUB.

Referring to FIGS. 3 and 4H, a memory package 20 may be provided.

In some example embodiments, the memory package 20 may include a second base substrate 201, a memory chip 202, a bonding wire 203 electrically connecting the memory chip 202 to an upper surface of the second base substrate 201 that faces away from the substrate SUB, a second mold layer 204 disposed on the second base substrate 201 and encapsulating or at least partially encapsulating the memory chip 202 and the bonding wire 203 on the second base substrate 201, and inter-chip solder balls 205 disposed on a lower surface of the second base substrate 201 opposite to the memory chip 202.

Next, the memory package 20 may be mounted on the upper surface of the lower thermal conductive layer 31 formed in FIG. 4G. In some example embodiments, the inter-chip solder balls 205 of the memory package 20 may be formed in the recess of the lower thermal conductive layer 31, and may be connected to the connection solder balls 106 and the system-on-chip chip 102 of the SOC package 10.

Referring to FIGS. 3 and 4I, a photoresist layer may be formed on the second mold layer 204 and patterned to form a plurality of openings, and the second mold layer 204 exposed in the plurality of openings may be partially removed using the photoresist pattern as an etching mask, to form recesses 211 in the second mold layer 204. The second mold layer 204 may be partially removed using a dry etching process. However, other suitable processes may also used and example embodiments are not limited in any respect with regards to the process used.

In pattern having a plurality of openings, when the second mold layer 204 is etched, in order to avoid damage to the bonding wire 203, the position and width of the recesses 211 may be determined in consideration of the height and position of the bonding wire 203.

In some example embodiments, the recesses 211 may not penetrate through the second mold layer 204. In other portions of the second mold layer 204, vias 207 that penetrate the entire memory package 20 (e.g., the entire vertical thickness of the memory package 20) may be formed. In some example embodiments, the via 207 may be formed through a drilling process or the like.

However, in some example embodiments, the drilling process may be performed first to form the via 207 penetrating the entire memory package 20. Then, a photolithography process using the photoresist may be performed on the upper surface of the second mold layer 204, to form the recesses 211 in the second mold layer 204.

Referring to FIGS. 3 and 4J, the photoresist pattern on the second mold layer 204 may be removed. Next, a high thermal conductive insulating material may be coated or formed on the upper surface of the memory package 20 to form an upper thermal conductive layer 32.

In the coating or forming process, the high thermal conductive insulating material may fill the recesses 211 formed in the memory package 20, and may pass through the via 207 and contact the lower thermal conductive layer 31. In addition, the high thermal conductive insulating material may also be coated or formed on a side surface of the memory package 20.

Next, a thermal conductive matrix 42 may be filled between the SOC package 10 and the substrate SUB, so that the thermal conductive matrix 42 coats the phase change composite material 44. In some example embodiments, a thermal interface material layer 40 may be formed. In some example embodiments, the thermal conductive matrix 42 may include, for example, thermal grease, but example embodiments are not limited thereto, and other thermally conductive materials may be used. In some example embodiments, the filling operation may be executed through an electroplating process or a screen printing process, but example embodiments are not limited thereto, and other suitable processes may be used.

Using the operations illustrated in FIGS. 4A-4J, the PoP package structure 3 of FIG. 3 having improved heat dissipation performance may be manufactured.

In order to manufacture the PoP package structure 3 illustrated in FIG. 3, operations such as curing the thermal conductive matrix 42 and/or thinning the upper thermal conductive layer 32 and/or the lower thermal conductive layer 31 may be performed in addition to the above operations to reduce a thickness of the high thermal conductive insulating material. However, other suitable operations are also within the scope of the disclosure for reducing the thickness of the high thermal conductive insulating material.

In other example embodiments, the operation in FIG. 4F may be omitted, whereas in FIG. 4J, the thermal conductive matrix 42 and the phase change composite material 44 are simultaneously filled in the space between the SOC package 10 and the substrate SUB. In addition, the order in which the SOC package 10, the memory package 20 and the substrate SUB are bonded to each other may be changed. For example, the SOC package 10 of FIG. 4E and the memory package 20 may be first bonded to each other, and then bonded to the substrate SUB of FIG. 4F.

The manufacturing method, according to example embodiments described in FIGS. 4A-4J, is directed to a heat dissipation process by transferring heat generated by the system-on-chip chip 102 upward through the lower thermal conductive layer 31 to the surface of the memory package 20, and downward through the lower thermal conductive layer 31 to the substrate SUB. The PoP package structure 2 illustrated in FIG. 2 may be manufactured using a process that may be same in some respects to processing illustrated in FIGS. 4A-4J, and a detailed description thereof is omitted herein for the sake of brevity. In the PoP package structure 2 illustrated in FIG. 2, heat generated by the system-on-chip chip 102 may be transferred downward through the thermal conductive layer 30 to the substrate SUB for dissipation, and may not be transferred upward through the thermal conductive layer 30 to the surface of the memory package 20.

According to some example embodiments of the present disclosure, in the PoP package structure, the higher thermal conductive insulating material may cover surfaces of the SOC package 10 and the memory package 20, and a vertical serial channel may be formed through the via penetrating the SOC package 10 and the memory package 20 (e.g., the first base substrate 101 and the second base substrate 201). The thermal conductive materials (e.g., thermal conductive insulating materials) inside the SOC package 10 and the memory package 20 may be connected in series. A lower portion of the SOC package 10 may be coated with a thermal interface material layer 40 formed of the thermal conductive matrix 42 (e.g., thermal grease) and the phase change composite material 44. Therefore, the heat generated by the system-on-chip chip 102 may be transferred downward through the lower thermal conductive layer 31 and the thermal interface material layer 40 to the substrate SUB, and/or may be transferred upward through the lower thermal conductive layer 31 and the upper thermal conductive layer 32 penetrating through the memory package 20 to the surface of the memory package 20. Thereby, the heat dissipation performance of the PoP package structure may be improved.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element, value, and/or property is referred to as being the same as another element, value, and/or property, it should be understood that an element, value, and/or property is the same as another element, value, and/or property within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A package-on-package (PoP) package structure, comprising:
a substrate;
a first package on the substrate, and including a first base substrate, a first chip on the first base substrate, and a first mold layer on the first base substrate and at least partially encapsulating the first chip;
a second package on the first package, and including a second base substrate, a second chip on the second base substrate, and a second mold layer on the second base substrate and at least partially encapsulating the second chip;
a first thermal conductive layer between an upper surface of the first package and a lower surface of the second package; and
a thermal interface material layer between a lower surface of the first package and an upper surface of the substrate,
wherein the first thermal conductive layer contacts the thermal interface material layer through a via defined in the first package.

2. The PoP package structure of claim 1, wherein the first thermal conductive layer comprises a thermal conductive insulating material.

3. The PoP package structure of claim 1, further comprising:
a second thermal conductive layer on an upper surface of the second package,
wherein the second thermal conductive layer contacts the first thermal conductive layer through a via penetrating the second package.

4. The PoP package structure of claim 3, wherein the second thermal conductive layer comprises a thermal conductive insulating material.

5. The PoP package structure of claim 4, wherein the first thermal conductive layer and the second thermal conductive layer comprise materials that are same as each other.

6. The PoP package structure of claim 4, wherein the first thermal conductive layer and the second thermal conductive layer comprise materials that are different from each other.

7. The PoP package structure of claim 3, wherein an upper surface of the second thermal conductive layer is at a same level as the upper surface of the second package.

8. The PoP package structure of claim 1, wherein the thermal interface material layer comprises a thermal conductive matrix and a phase change composite material dispersed in the thermal conductive matrix.

9. The PoP package structure of claim 8, wherein the thermal conductive matrix has an insulating property.

10. The PoP package structure of claim 8, wherein the phase change composite material comprises a phase change material and a wrapping material wrapping the phase change material.

11. A method of manufacturing a package-on-package (PoP) package structure, comprising:
providing a first package including a first base substrate, a first chip on the first base substrate, and a first mold layer on the first base substrate and at least partially encapsulating the first chip;
performing a drilling process on the first package to form a first via penetrating the first package;
coating a high thermal conductive insulating material on an upper surface of the first package to form a first thermal conductive layer;
coating a phase change composite material on an upper surface of a substrate;
bonding the first package formed with a first thermal conductive layer on the upper surface thereof and the substrate coated with the phase change composite material on the upper surface thereof with each other;
providing a second package including a second base substrate, a second chip on the second base substrate, and a second mold layer on the second base substrate and at least partially encapsulating the second chip;
bonding the second package and the first package bonded to the substrate with each other; and
filing a thermal conductive matrix in a space between the substrate and the first package, to form a thermal interface material layer,
wherein the first thermal conductive layer is in contact with the thermal interface material layer through the first via.

12. The method of claim 11, further comprising:
after forming the first thermal conductive layer, performing an etching process on the upper surface of the first thermal conductive layer to form a first recess.

13. The method of claim 11, further comprising:
performing an etching process on an upper surface of the second package to form a second recess;
performing a drilling process on the second package to form a second via penetrating the second package; and
coating a thermal conductive insulating material on the upper surface of the second package to form a second thermal conductive layer,
wherein the second thermal conductive layer fills the second recess and the second via, and contacts the first thermal conductive layer through the second via.

14. The method of claim 13, wherein the first thermal conductive layer and the second thermal conductive layer comprise thermal conductive insulating materials that are same as each other.

15. The method of claim 13, wherein the first thermal conductive layer and the second thermal conductive layer comprise thermal conductive insulating materials that are different from each other.

16. The method of claim 13, wherein an upper surface of the second thermal conductive layer is at a same level as the upper surface of the second package.

17. The method of claim 11, wherein the thermal conductive matrix has an insulating property.

18. The method of claim 11, wherein the phase change composite material comprises a phase change material and a wrapping material wrapping the phase change material.
